(19) United States
(12) Patent Application Publication
(10) Pub. No.: US 2016/0247710 A1
(43) Pub. Date: Aug. 25, 2016

(54) SEMICONDUCTOR DEVICE AND METHOD OF MANUFACTURING THE SAME

(71) Applicant: Kabushiki Kaisha Toshiba, Minato-ku (JP)

(72) Inventors: Toshiyuki Morita, Yokkaichi (JP); Jun Takayasu, Yokkaichi (JP)

(73) Assignee: Kabushiki Kaisha Toshiba, Minato-ku (JP)

(21) Appl. No.: 14/796,409

(22) Filed: Jul. 10, 2015

Related U.S. Application Data
(60) Provisional application No. 62/118,702, filed on Feb. 20, 2015.

(51) Int. Cl. H01L 21/768; H01L 21/311; H01L 23/532; H01L 21/02; H01L 23/522; H01L 23/528

(52) U.S. Cl. CPC H01L 21/7682; H01L 21/76834; H01L 23/5226; H01L 23/528; H01L 23/5329; H01L 21/76802; H01L 21/76877; H01L 21/02247; H01L 21/31111; H01L 23/53238; H01L 21/76843

(57) ABSTRACT

In one embodiment, a method of manufacturing a semiconductor device includes forming plugs in a first insulator, and forming a first film on the first insulator and the plugs. The method further includes forming openings in the first film to expose the plugs in the openings, and forming a second insulator on side faces of the openings. The method further includes forming an interconnect material adjacent to the second insulator in the openings to form interconnects including the interconnect material on the plugs in the openings. The method further includes removing the first film after forming the interconnects, and forming a third insulator on the interconnects to form an air gap between the interconnects.

### CROSS REFERENCE TO RELATED APPLICATION

This application is based upon and claims the benefit of priority from the prior U.S. Provisional Patent Application No. 62/118,702 filed on Feb. 20, 2015, the entire contents of which are incorporated herein by reference.

### FIELD

Embodiments described herein relate to a semiconductor device and a method of manufacturing the same.

### BACKGROUND

In recent years, there has been a request to form an air gap between copper (Cu) interconnects. For example, the air gap can be formed by forming the Cu interconnects in a sacrificial film via a barrier metal layer, removing the sacrificial film after the Cu interconnects are formed, and forming an insulator having a poor embedding property on the Cu interconnects after the sacrificial film is removed. However, there is a problem in this case that options of materials of the barrier metal layer and the sacrificial film are limited.

For example, it is considered that the barrier metal layer is a titanium (Ti) layer, the sacrificial film is a silicon oxide film, and a method of removing the sacrificial film is wet etching with diluted hydrofluoric acid. However, there is a problem in this case that when the sacrificial film is removed, the barrier metal layer is etched.

For example, such etching of the barrier metal layer can be suppressed by wet etching in which the barrier metal layer is a Ti layer, the sacrificial film is an amorphous silicon film, and the method of removing the sacrificial film is wet etching with TMY (trimethyl-2-hydroxyethylammonium hydroxide). However, there is a problem in this case that the planarization of the sacrificial film cannot employ chemical mechanical polishing (CMP). The reason is that since the amorphous silicon film has high water repellency, it is difficult to wash away and remove dusts generated by CMP from the amorphous silicon film.

These problems can arise also in a case where the air gap is formed between interconnects other than the Cu interconnects.

### BRIEF DESCRIPTION OF THE DRAWINGS

FIGS. 1A to 3B are cross-sectional views illustrating a method of manufacturing a semiconductor device of a first embodiment; and

FIGS. 4A to 6B are cross-sectional views illustrating a method of manufacturing a semiconductor device of a second embodiment.

### DETAILED DESCRIPTION

Embodiments will now be explained with reference to the accompanying drawings.

In one embodiment, a method of manufacturing a semiconductor device includes forming plugs in a first insulator, and forming a first film on the first insulator and the plugs. The method further includes forming openings in the first film to expose the plugs in the openings, and forming a second insulator on side faces of the openings. The method further includes forming an interconnect material adjacent to the second insulator in the openings to form interconnects including the interconnect material on the plugs in the openings. The method further includes removing the first film after forming the interconnects, and forming a third insulator on the interconnects to form an air gap between the interconnects.

### First Embodiment

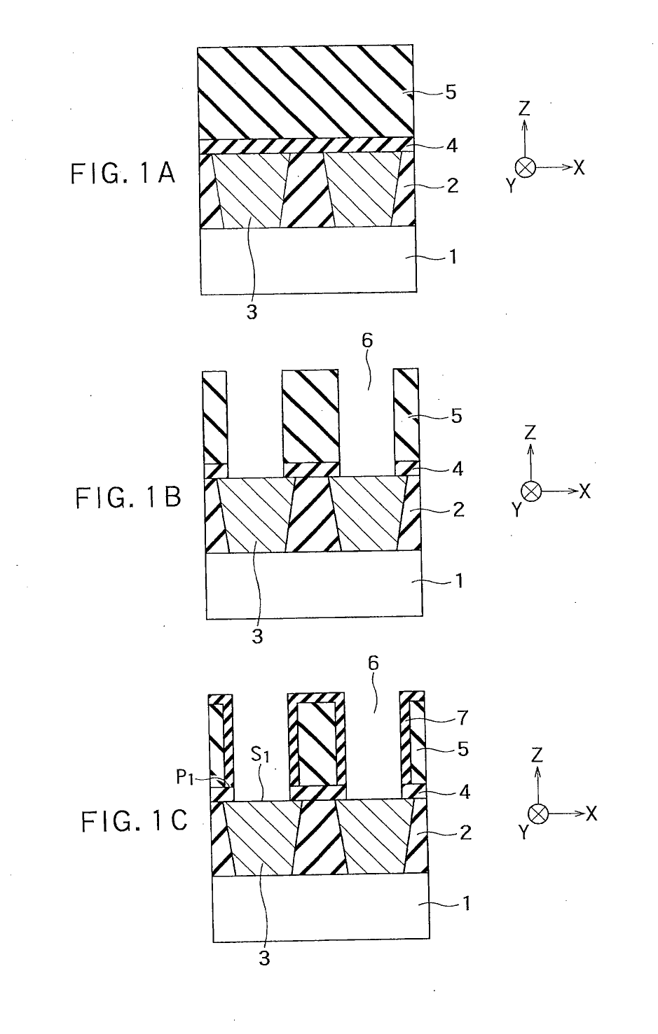

FIGS. 1A to 3B are cross-sectional views illustrating a method of manufacturing a semiconductor device of a first embodiment.

[FIG. 1A]

First, a first insulator 2 is formed on a substrate 1, contact plugs 3 are formed in the first insulator 2, and a sacrificial film 5 is formed on the first insulator 2 and the contact plugs 3 via a ground insulator 4 (FIG. 1A). The contact plugs 3 are an example of plugs of the disclosure. The ground insulator 4 is an example of an insulator of the disclosure. The sacrificial film 5 is an example of a first film of the disclosure.

An example of the substrate 1 is a semiconductor substrate such as a silicon substrate. FIG. 1A illustrates a X-direction and a Y-direction which are parallel to a surface of the substrate 1 and perpendicular to each other, and a Z-direction perpendicular to the surface of the substrate 1. In the specification, the +Z-direction is regarded as an upward direction and the −Z-direction is regarded as a downward direction. For example, positional relation between the substrate 1 and the first insulator 2 is expressed as that the substrate 1 is positioned below the first insulator 2. The −Z-direction of the present embodiment may coincide with the direction of gravity or may not coincide with the direction of gravity.

An example of the first insulator 2 is a silicon nitride film. The first insulator 2 may be formed directly on the substrate 1 or may be formed on the substrate 1 via another layer. The first insulator 2 may be a stacked layer including plural insulators. The first insulator 2 is, for example, an inter layer dielectric covering transistors and the like on the substrate 1.

An example of each contact plugs 3 is a tungsten (W) layer. For example, the contact plugs 3 are formed by forming contact holes which penetrate the first insulator 2, embedding a plug material of the contact plugs 3 in the contact holes, and removing the extra plug material outside the contact holes. For example, the contact plugs 3 are electrically connected to diffusion layers in the substrate 1.

An example of the ground insulator 4 is a silicon nitride film. An example of the sacrificial film 5 is a silicon oxide film (or a tetraethyl orthosilicate (TEOS) film).

[FIG. 1B]

Next, openings 6 are formed to penetrate the sacrificial film 5 and the ground insulator 4 and to reach the contact plugs 3 by lithography and reactive ion etching (RIE) (FIG. 1B). As a result, the contact plugs 3 are exposed in the openings 6. Each opening 6 of the present embodiment has a shape extending in the Y-direction.

[FIG. 1C]

Next, the sacrificial film 5 is nitrided to form a second insulator 7 as a nitride film on side faces and upper faces of the sacrificial film 5 (FIG. 1C). An example of the second insulator 7 is a silicon oxynitride film (SiON). An example of a thickness of the second insulator 7 is 2 nm to 3 nm. For example, the nitridation of the sacrificial film 5 is performed by plasma nitridation. The nitridation of the sacrificial film 5 is an example of a chemical reaction of the first film of the disclosure.

In this way, since the second insulator 7 of the present embodiment is formed by nitridation, most of the second insulator 7 is formed inside the sacrificial film 5, not outside the sacrificial film 5. Therefore, the second insulator 7 of the present embodiment can be formed substantially without reducing the opening area of the openings 6.

Moreover, since the second insulator 7 of the present embodiment is formed by nitridation, the second insulator 7 is substantially not formed in the ground insulator 4 which is a silicon nitride film and in the contact plugs 3 which are tungsten layers. Therefore, when an interconnect material is embedded in the openings 6, the present embodiment can embed the interconnect material without a process of removing the second insulator 7 from bottom faces of the openings 6.

Sign S₁ designates the bottom faces of the openings 6 (upper faces of the contact plugs 3). Sign P₁ designates lower ends of the second insulator 7. Since the second insulator 7 of the present embodiment is formed on the surface of the sacrificial film 5 and not formed on the surfaces of the ground insulator 4 and the contact plugs 3, the lower ends P₁ of the second insulator 7 are higher than the bottom faces S₁ of the openings 6. The second insulator 7 of the present embodiment is not formed on the bottom faces S₁ of the openings 6 but is formed on the side faces of the openings 6.

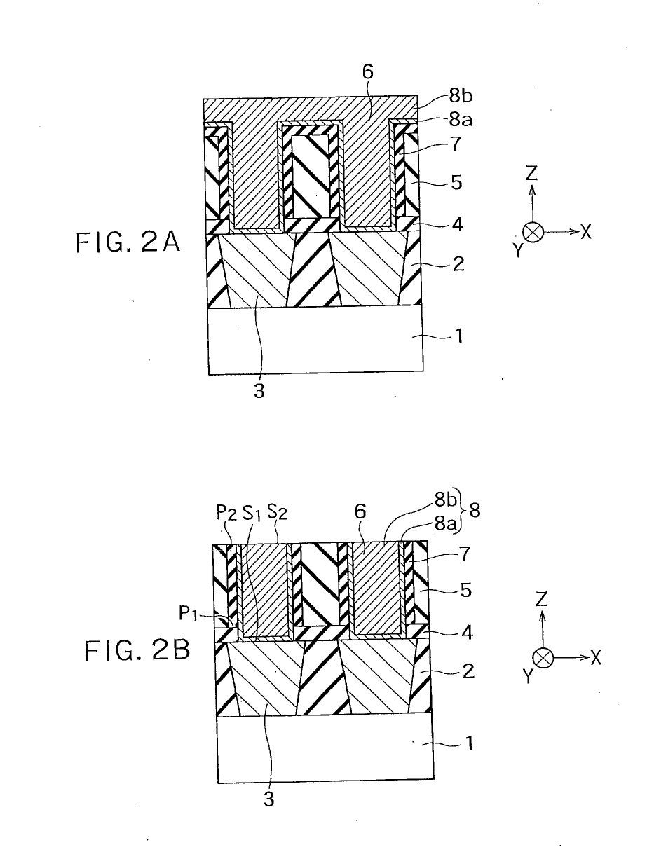

It is considered that the second insulator 7 of the present embodiment is formed by chemical vapor deposition (CVD) in place of the nitridation. However, if the second insulator 7 is formed by CVD, the second insulator 7 is also formed on the bottom faces S₁ of the openings 6, so that the second insulator 7 is needed to be removed from the bottom faces S₁ of the openings 6. Moreover, if the second insulator 7 is formed by CVD, the second insulator 7 is also formed outside the sacrificial film 5, so that the opening area of the openings 6 becomes small. Therefore, the second insulator 7 of the present embodiment is desirable to be formed by nitridation.

[FIG. 2A]

Next, a first interconnect material 8a is formed on the whole surface of the substrate 1 by sputtering (FIG. 2A). As a result, the first interconnect material 8a adjacent to the second insulator 7 is formed in the openings 6. The first interconnect material 8a is formed on the side faces and the bottom faces of the openings 6, is in contact with the second insulator 7 on the side faces of the openings 6, and is in contact with the contact plugs 3 on the bottom faces of the openings 6. An example of the first interconnect material 8a is a titanium (Ti) layer. The first interconnect material 8a functions as a barrier metal layer.

The first interconnect material 8a of the present embodiment may be a tantalum (Ta) layer in place of the Ti layer. The Ta layer has a merit of having high durability against wet etching as compared with the Ti layer. On the other hand, the Ti layer has a merit of achieving close contact with copper and a merit of cheapness as compared with the Ta layer. In the present embodiment, the Ti layer is employed as the first interconnect material 8a since the second insulator 7 can protect the first interconnect material 8a from the wet etching as mentioned later.

A second interconnect material 8b is then formed on the whole surface of the substrate 1 by plating (FIG. 2A). As a result, the second interconnect material 8b is formed on the first interconnect material 8a, and the first and second interconnect materials 8a and 8b adjacent to the second insulator 7 are formed in the openings 6. An example of the second interconnect material 8b is a Cu (copper) layer.

[FIG. 2B]

Next, the surfaces of the first and second interconnect materials 8a and 8b are planarized by CMP (FIG. 2B). As a result, interconnects 8 including the first and second interconnect materials 8a and 8b are formed on the contact plugs 3 in the openings 6. The first and second interconnect materials 8a and 8b of the present embodiment are planarized until the upper faces of the sacrificial film 5 are exposed. As a result, the height of upper faces S₂ of the interconnects 8 becomes the same as the height of upper ends P₂ of the second insulator 7. Meanwhile, the height of lower faces of the interconnects 8 becomes the same as the height of the lower faces S₁ of the openings 6, and becomes lower than the height of the lower ends P₁ of the second insulator 7. Each interconnect 8 of the present embodiment have a shape extending in the Y-direction.

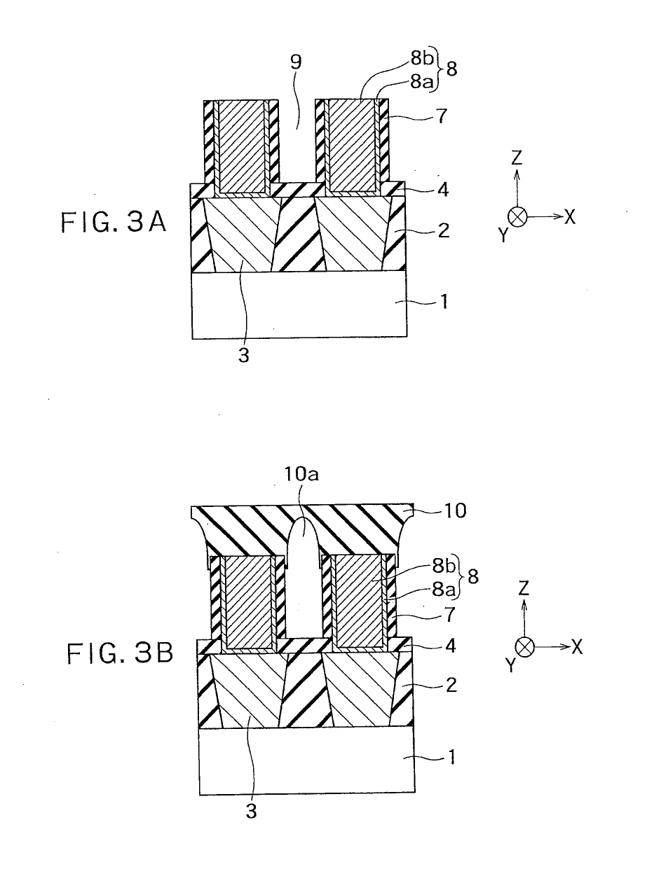

Since the sacrificial film 5 of the present embodiment is a silicon oxide film, it can be planarized by CMP. Therefore, in the process of FIG. 2B, the CMP can be employed to planarize the first and second interconnect materials 8a and 8b. In the last stage of the process of FIG. 2B, the surface of the sacrificial film 5 is also planarized by CMP.

[FIG. 3A]

Next, the sacrificial film 5 is removed by wet etching (FIG. 3A). As a result, openings 9 are formed between the interconnects 8. The second insulator 7 is exposed on side faces of the openings 9, and the ground insulator 4 is exposed on bottom faces of the openings 9. The sacrificial film 5 of the present embodiment is removed using an acidic chemical such as diluted hydrofluoric acid.

The sacrificial film 5 of the present embodiment is the silicon oxide film and the second insulator 7 of the present embodiment is the silicon oxynitride film. Therefore, the sacrificial film 5 of the present embodiment is removed using diluted hydrofluoric acid. Meanwhile, when the second insulator 7 is the silicon oxynitride film, nitrogen in the second insulator 7 impedes reaction of the second insulator 7 with the diluted hydrofluoric acid. Therefore, in the wet etching of the present embodiment, the sacrificial film 5 can be removed with the second insulator 7 remaining.

Therefore, during continuing the wet etching of the present embodiment, the first interconnect material 8a is covered by the second insulator 7. The first interconnect material 8a of the present embodiment is the Ti layer, which has a property of being liable to be etched with diluted hydrofluoric acid. However, according to the present embodiment, the first interconnect material 8a can be protected from diluted hydrofluoric acid by the second insulator 7, which can suppress etching of the first interconnect material 8a.

In the wet etching of the present embodiment, upper ends of the first interconnect material 8a are exposed from the second insulator 7. Therefore, the upper ends of the first interconnect material 8a are etched with diluted hydrofluoric acid in the wet etching. However, exposed areas of the upper ends of the first interconnect material 8a are quite small. Therefore, according to the present embodiment, the etching amount of the first interconnect material 8a can be efficiently reduced by protecting the first interconnect material 8a with the second insulator 7 as compared with a case where the first interconnect material 8a is not protected with the second insulator 7.

[FIG. 3B]

Next, a third insulator 10 is formed on the whole surface of the substrate 1 (FIG. 3B). As a result, air gaps 10a are formed in the openings 9 between the interconnects 8. For example, the air gaps 10a can be formed by using, as the third insulator 10, an insulator having a poor embedding property. An example of the third insulator 10 is a silicon carbonitride film (SiCN).

The third insulator 10 of the present embodiment may come into the openings 9 as long as the air gaps 10a are formed in the opening 9 between the interconnects 8. For example, the third insulator 10 may be formed on the side faces and the bottom faces of the openings 9 such that the air gaps 10a are surrounded by the third insulator 10.

Thereafter, various inter layer dielectrics, via plugs, interconnect layers and the like are formed on the substrate 1 in the present embodiment. In this way, the semiconductor device of the present embodiment is manufactured.

As described above, in the present embodiment, the openings 6 are formed in the sacrificial film 5, the second insulator 7 is formed on the side faces of the openings 6, the interconnects 8 adjacent to the second insulator 7 are formed in the openings 6, and the sacrificial film 5 is removed after forming the interconnects 8. Accordingly, the first interconnect material 8a in the present embodiment can be protected from the wet etching by the second insulator 7. Therefore, according to the present embodiment, wide options of the materials of the sacrificial film 5 and the first interconnect material 8a are possible; for example, a silicon oxide film to which the CMP is applicable can be employed as the sacrificial film 5, and a Ti layer which achieves close contact with copper can be employed as the first interconnect material 8a.

As the second insulator 7 of the present embodiment, an insulator which has a merit also after the completion of the semiconductor device may be used. For example, when the first interconnect material 8a is the Ti layer, the first interconnect material 8a is liable to be oxidized. In this case, when the second insulator 7 is a silicon oxynitride film, the oxidation of the first interconnect material 8a can be suppressed by the second insulator 7, which can improve the reliability of the interconnects 8.

### Second Embodiment

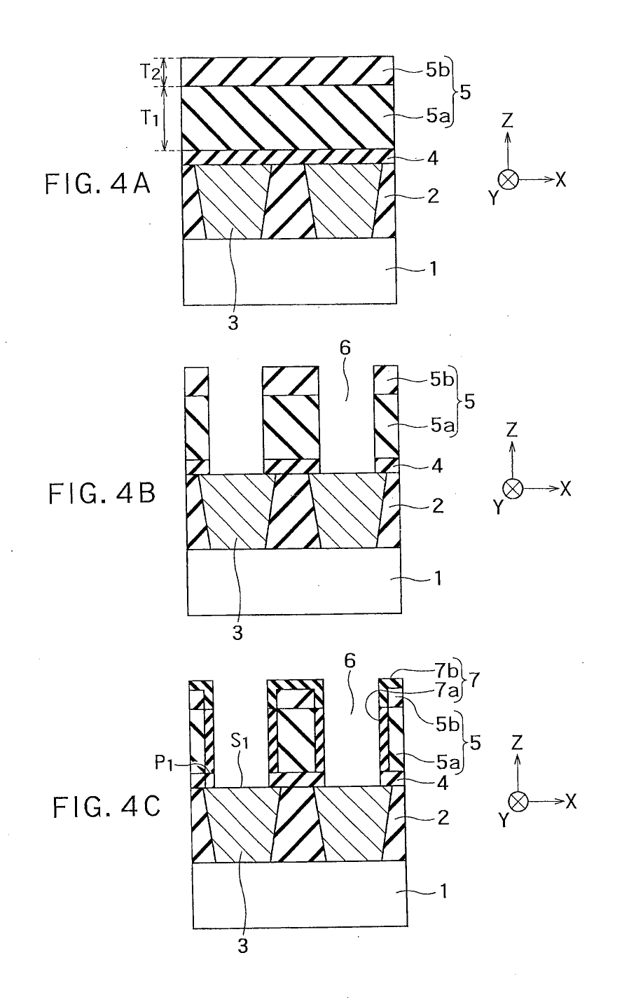

FIGS. 4A to 6B are cross-sectional views illustrating a method of manufacturing a semiconductor device of a second embodiment. In the description of the present embodiment, explanation of the matters common to the first embodiment is omitted.

[FIG. 4A]

First, the first insulator 2 is formed on the substrate 1, the contact plugs 3 are formed in the first insulator 2, and the sacrificial film 5 is formed on the first insulator 2 and the contact plugs 3 via the ground insulator 4 (FIG. 4A). Examples of the substrate 1, the first insulator 2, the contact plugs 3 and the ground insulator 4 are a silicon substrate, a silicon nitride film, tungsten layers and a silicon nitride film, respectively.

The sacrificial film 5 of the present embodiment includes a first layer 5a formed on the ground insulator 4, and a second layer 5b formed on the first layer 5a. An example of the first layer 5a is an amorphous silicon film. An example of the second layer 5b is a silicon oxide film (or a TEOS film). In the present embodiment, a thickness T₂ of the second layer 5b is configured to be smaller than a thickness T₁ of the first layer 5a.

[FIG. 4B]

Next, the openings 6 are formed to penetrate the sacrificial film 5 and the ground insulator 4 and to reach the contact plugs 3 by lithography and the RIE (FIG. 4B). As a result, the contact plugs 3 are exposed in the openings 6.

[FIG. 4C]

Next, the sacrificial film 5 is nitrided to form the second insulator 7 which is a nitride film on the side faces and the upper faces of the sacrificial film 5 (FIG. 4C).

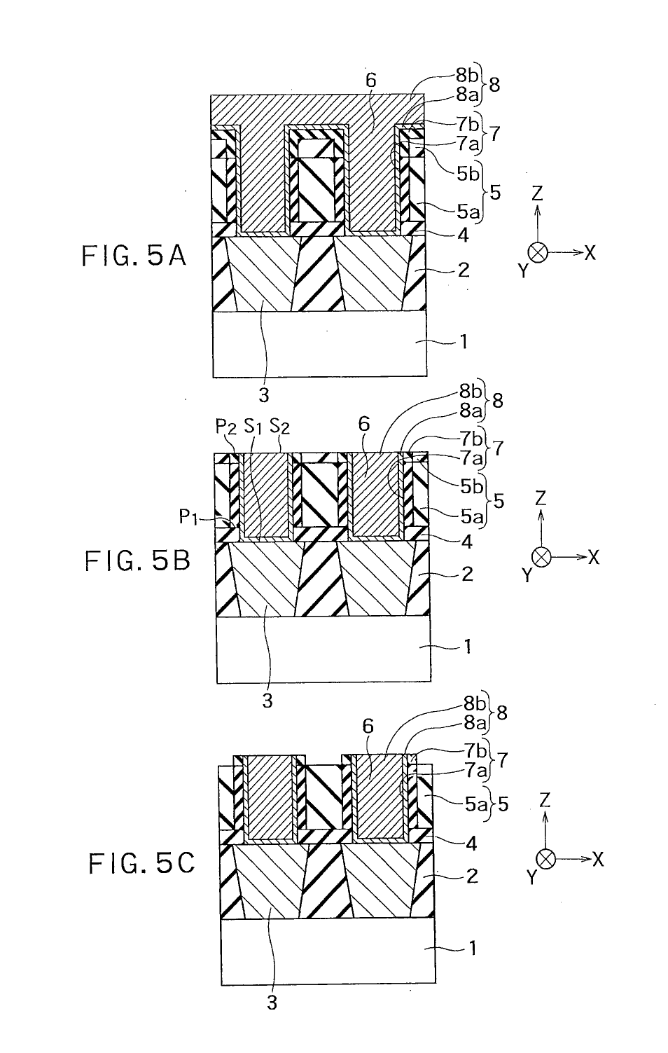

The second insulator 7 of the present embodiment includes a first portion 7a formed on side faces of the first layer 5a, and a second portion 7b formed on side faces and an upper face of the second layer 5b. An example of the first portion 7a is a silicon nitride film formed by nitridation of the amorphous silicon film. An example of the second portion 7b is a silicon oxynitride film formed by nitridation of the silicon oxide film. The first portion 7a has the lower ends P₁ higher than the bottom faces S₁ of the openings 6. The second portion 7b is positioned above the first portion 7a.

[FIG. 5A]

Next, the first interconnect material 8a is formed on the whole surface of the substrate 1 by sputtering (FIG. 5A). As a result, the first interconnect material 8a adjacent to the second insulator 7 is formed in the openings 6. An example of the first interconnect material 8a is the Ti layer.

The second interconnect material 8b is then formed on the whole surface of the substrate 1 by plating (FIG. 5A). As a result, the second interconnect material 8b is formed on the first interconnect material 8a, and the first and second interconnect materials 8a and 8b adjacent to the second insulator 7 are formed in the openings 6. An example of the second interconnect material 8b is the Cu layer.

[FIG. 5B]

Next, the surfaces of the first and second interconnect materials 8a and 8b are planarized by CMP (FIG. 5B). As a result, the interconnects 8 including the first and second interconnect materials 8a and 8b are formed on the contact plugs 3 in the openings 6. The first and second interconnect materials 8a and 8b of the present embodiment are planarized until upper faces of the second layer 5b of the sacrificial film 5 are exposed. As a result, the height of the upper faces S₂ of the interconnects 8 becomes the same as the height of the upper ends P₂ of the second portion 7b in the second insulator 7. Meanwhile, the height of the lower faces of the interconnects 8 becomes the same as the height of the lower faces S₁ of the openings 6, and becomes lower than the height of the lower ends P₁ of the first portion 7a in the second insulator 7.

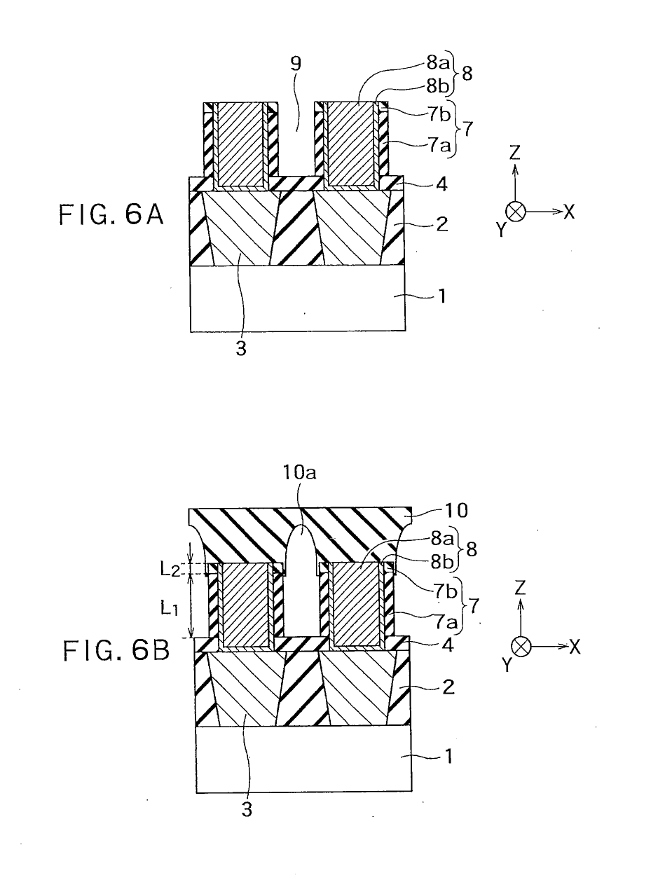

Since the second layer 5b of the sacrificial film 5 of the present embodiment is the silicon oxide film, it can be planarized by CMP. Therefore, in the process of FIG. 5B, the CMP can be employed to planarize the first and second interconnect materials 8a and 8b. In the last stage of the process of FIG. 5B, the surface of the second layer 5b of the sacrificial film 5 is also planarized by CMP.

[FIGS. 5C and 6A]

Next, the second layer 5b of the sacrificial film 5 is removed by first wet etching using a first chemical (FIG. 5C). The first layer 5a of the sacrificial film 5 is then removed by second wet etching using a second chemical different from the first chemical (FIG. 5C). As a result, the openings 9 are formed between the interconnects 8. The second insulator 7 is exposed on the side faces of the openings 9, and the ground insulator 4 is exposed on the bottom faces of the openings 9. An example of the first chemical is an acidic chemical such as diluted hydrofluoric acid. An example of the second chemical is a basic chemical such as hot TMY.

The second layer 5b of the sacrificial film 5 of the present embodiment is the silicon oxide film, and the second portion 7b of the second insulator 7 of the present embodiment is the silicon oxynitride film. Therefore, the second layer 5b of the present embodiment is removed using diluted hydrofluoric acid. Meanwhile, when the second portion 7b is the silicon oxynitride film, nitrogen in the second portion 7b impedes reaction of the second portion 7b with the diluted hydrofluoric acid. Therefore, in the first wet etching of the present embodiment, the second layer 5b of the sacrificial film 5 can be removed with the second portion 7b of the second insulator 7 remaining.

Therefore, during continuing the first wet etching of the present embodiment, the first interconnect material 8a is covered by the second portion 7b of the second insulator 7. The first interconnect material 8a of the present embodiment is the Ti layer, which has the property of being liable to be etched with diluted hydrofluoric acid. However, according to the present embodiment, the first interconnect material 8a can be protected from diluted hydrofluoric acid by the second portion 7b, which can suppress etching of the first interconnect material 8a.

Moreover, the first layer 5a of the sacrificial film 5 of the present embodiment is the amorphous silicon film. Therefore, the first layer 5a of the present embodiment is removed using TMY. Meanwhile, the first interconnect material 8a of the present embodiment is the Ti layer, which has a property that it is almost not etched with TMY. Therefore, in the second wet etching of the present embodiment, while etching of the first interconnect material 8a is suppressed, the first layer 5a of the sacrificial film 5 can be removed. In the second wet etching of the present embodiment, the first and second portions 7a and 7b of the second insulator 7 also remain.

In the first wet etching of the present embodiment, the upper ends of the first interconnect material 8a are exposed from the second portion 7b of the second insulator 7. Therefore, the upper ends of the first interconnect material 8a are etched with the diluted hydrofluoric acid in the first wet etching. However, in contrast to the first embodiment where all of the sacrificial film 5 is removed with the diluted hydrofluoric acid, only the second layer 5b of the sacrificial film 5 is removed with the diluted hydrofluoric acid in the present embodiment. Therefore, according to the present embodiment, the etching amount of the first interconnect material 8a can be reduced as compared with the first embodiment. The etching amount of the first interconnect material 8a can be reduced by reducing the ratio T₂/T₁ of the thickness T₂ of the second layer 5b to the thickness T₁ of the first layer 5a.

[FIG. 6B]

Next, the third insulator 10 is formed on the whole surface of the substrate 1 (FIG. 6B). As a result, the air gaps 10a are formed in the openings 9 between the interconnects 8. An example of the third insulator 10 is a silicon carbonitride film.

Sign L₁ designates the length of the first portion 7a of the second insulator 7 in the vertical direction (Z-direction). Sign L₂ designates the length of the second portion 7b of the second insulator 7 in the vertical direction. In the present embodiment, the length L₂ of the second portion 7b is smaller than the length L₁ of the first portion 7a.

Thereafter, various inter layer dielectrics, via plugs, interconnect layers and the like are formed on the substrate 1 in the present embodiment. In this way, the semiconductor device of the present embodiment is manufactured.

As described above, the sacrificial film 5 of the present embodiment includes the first layer 5a and the second layer 5b formed on the first layer 5a. Therefore, the first layer 5a in the present embodiment can be formed of a material which can be removed with a chemical with which the first interconnect material 8a is not etched. Moreover, the second layer 5b in the present embodiment can be formed of a material to which the CMP can be applied. Thereby, the present embodiment can reduce the etching amount of the first interconnect material 8a when the sacrificial film 5 is removed, as compared with the first embodiment.

On the other hand, according to the first embodiment, the number of processes in the removing process of the sacrificial film 5 can be reduced as compared with the present embodiment.

The first and second embodiments can also be applied to interconnects formed on via plugs as well as the interconnects 8 formed on the contact plugs 3.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A method of manufacturing a semiconductor device, comprising:
forming plugs in a first insulator;
forming a first film on the first insulator and the plugs;
forming openings in the first film to expose the plugs in the openings;
forming a second insulator on side faces of the openings;
forming an interconnect material adjacent to the second insulator in the openings to form interconnects including the interconnect material on the plugs in the openings;
removing the first film after forming the interconnects; and
forming a third insulator on the interconnects to form an air gap between the interconnects.

2. The method of claim 1, wherein the second insulator is formed on a surface of the first film by chemical reaction of the first film.

3. The method of claim 2, wherein the chemical reaction is nitridation of the first film.

4. The method of claim 1, wherein the first film is formed on the first insulator and the plugs via an insulator.

5. The method of claim 1, wherein the second insulator is formed such that a lower end of the second insulator is higher than bottom faces of the openings.

6. The method of claim 1, wherein the first film is removed with the second insulator remaining.

7. The method of claim 1, wherein the first film is removed using an acidic chemical.

8. The method of claim 1, wherein the interconnect material includes a first interconnect material formed adjacent to the second insulator in the openings, and a second interconnect material formed on the first interconnect material.

9. The method of claim 8, wherein the first interconnect material contains titanium or tantalum, and the second interconnect material contains copper.

10. The method of claim 1, wherein the first film includes a first layer formed on the first insulator and the plugs, and a second layer formed on the first layer.

11. The method of claim 10, wherein a thickness of the second layer is smaller than a thickness of the first layer.

12. The method of claim 10, wherein the second insulator includes a first portion formed on a surface of the first layer by chemical reaction of the first layer, and a second portion formed on a surface of the second layer by chemical reaction of the second layer.

13. The method of claim 12, wherein the first film is removed with the first and second portions remaining.

14. The method of claim 10, wherein the second layer is removed using a first chemical, and the first layer is removed using a second chemical different from the first chemical.

15. The method of claim 14, wherein the first chemical is an acidic chemical, and the second chemical is a basic chemical.

16. A semiconductor device comprising:
a first insulator;
plugs provided in the first insulator;
interconnects provided on the plugs;
a second insulator provided on side faces of the interconnects and having a lower end higher than lower faces of the interconnects; and
a third insulator provided on the interconnects so as to provide an air gap between the interconnects.

17. The device of claim 16, wherein the second insulator contains nitrogen.

18. The device of claim 16, wherein one of the interconnects includes a first interconnect material in contact with the second insulator and one of the plugs, and a second interconnect material provided on the first interconnect material.

19. The device of claim 16, wherein the second insulator includes a first portion formed of a first material, and a second portion formed of a second material different from the first material and disposed on the first portion.

20. The device of claim 19, wherein a length of the second portion in a vertical direction is smaller than a length of the first portion in the vertical direction.
